(19) United States
(12) Patent Application Publication
(10) Pub. No.: US 2011/0241156 A1
(43) Pub. Date: Oct. 6, 2011

(54) SEMICONDUCTOR DEVICE AND METHOD FOR MANUFACTURING THE SAME

(76) Inventor: Shengan Xiao, Shanghai (CN)

(21) Appl. No.: 13/080,582

(22) Filed: Apr. 5, 2011

(30) Foreign Application Priority Data
Apr. 6, 2010 (CN) 201010141064.5

(51) Int. Cl. H01L 29/06; H01L 21/20

(52) U.S. Cl. 257/487; 438/482; 438/488; 438/478; 257/E21.09; 257/E29.005

(57) ABSTRACT

Methods for manufacturing a semiconductor device with alternating P type and N type semiconductor conductive regions are disclosed. One method includes forming a trench in an N type epitaxial layer; forming carbon-contained silicon layer on sidewalls of the trench; and filling the trench with P type semiconductor layer. In another method, the carbon-contained silicon layer is replaced by a carbon film formed by diffusion process. The carbon-contained silicon layer or the carbon film can effectively inhibit the diffusion of P type impurities into the N type semiconductor layers. Further, a semiconductor device having carbon-contained layer or carbon film formed between P type and N type conductive layers is also disclosed.

### CROSS-REFERENCES TO RELATED APPLICATIONS

This application claims the priority of Chinese patent application number 201010141064.5, filed on Apr. 6, 2010, the entire contents of which are incorporated herein by reference.

### FIELD OF THE INVENTION

The invention relates to power semiconductor devices, and more particularly, to a superjunction MOSFET with alternating P type and N type conductive regions and a method for manufacturing the same.

### BACKGROUND

A superjunction MOSFET (metal oxide semiconductor field effect transistor) adopts a new voltage-withstanding structure consisting of a series of alternating P type and N type semiconductor conductive regions. In an off-state, both P type and N type regions can be fully depleted at a relatively low voltage by charge compensation, thereby exhibiting a high breakdown voltage even if the P type and N type doping regions have a much higher impurity concentration than a conventional device. Moreover, the device may also achieve a low on-resistance as the impurity concentration of the doping regions in a superjunction MOSFET is several times higher than that of a conventional MOSFET. Therefore, a superjunction MOSFET may simultaneously achieve a high breakdown voltage and a low on-resistance. Its device performance may surpass the performance limit of a conventional MOSFET.

Currently, there are two ways of manufacturing the above mentioned new voltage-withstanding structure consisting of a series of alternating P type and N type semiconductor conductive regions. One way is by multiple epitaxial processes: grow a first thin epitaxial film on a substrate and implant impurity into the first film; grow a second thin epitaxial film on the first film and implant impurity into the second film at the same position; repeat the steps of epitaxial growth and impurity implantation, wherein the doping regions are aligned with one another. The other way is by trench process: firstly, form a trench in an N type epitaxial layer by etch; then, fill the trench with P type silicon by epitaxial growth or tilt angle implantation. The first way of multiple epitaxial processes is not only complex and costly, but also difficult to implement, while in the second way of trench process, the method of trench filling by eptaxial growth is attracting more and more attention due to its relatively low cost, although this process is difficult to control.

After the formation of alternating conductive regions, no matter by multiple epitaxial process or by trench process, the wafers need to go through high temperature processes such as oxidation by furnace, well drive-in, anneal after source/drain implantation, reflow of BPSG, etc. These high temperature processes may cause the diffusion of P type impurities into N type regions, and some of the N type carriers in the N type regions will be neutralized by the P type impurities. As a result, the number of N type carriers in the drift region decreases, thus increasing the Rsp (specific on resistance) of the device in an on-state.

To minimize this effect, one way is to perform well drive-in process before the deposition of P type silicon films. However, this method will limit the flexibility of process integration. Moreover, other high temperature processes that can not be performed prior to the formation of silicon films, such as gate oxidation growth, anneal after source/drain implantation, reflow of BPSG, etc. may also have great impact on the diffusion of P type impurities. The impact becomes even more outstanding when the device is designed at a relatively low breakdown voltage like 200V or below.

### SUMMARY OF THE INVENTION

The objective of the present invention is to provide a method for manufacturing semiconductor device to mitigate the diffusion of P type carriers (boron) into N type semiconductor conductive regions, and thereby achieving a relatively low Rsp (specific on resistance).

To achieve the aforementioned objective, one aspect of the present invention includes a method for manufacturing a semiconductor device having alternating P type and N type semiconductor conductive regions, which comprises the following steps:

step 1: form a first type epitaxial layer on a first type substrate; deposit a dielectric layer on the first type epitaxial layer; form a trench in the first type epitaxial layer by lithography and etch; wherein, the first type substrate has a high impurity concentration;

step 2: deposit a carbon-contained silicon layer on side walls of the trench, wherein the carbon-contained silicon layer can be N-typed, P-typed or intrinsic;

step 3: fill the trench by depositing a second type semiconductor layer, wherein the second type semiconductor layer is a single layer of second type silicon, or a combination of a second type silicon layer and a dielectric film, or a combination of a second type silicon layer and a non-doped silicon layer;

The second type semiconductor layer can be made of monocrystal silicon, polycrystal silicon or amorphous silicon; the growth temperature of monocrystal silicon can be in a range of 650-1200; the growth temperature of polycrystal silicon can be in a range of 580-650; the growth temperature of amorphous silicon can be in a range of 510-579.

step 4: remove a part of the second type semiconductor layer, the carbon-contained silicon layer and the dielectric layer above the first type epitaxial layer by CMP (chemical mechanical polish) or etch-back process;

In the above-mentioned method, the first type is N type when the second type is P type; the first type is P type when the second type is N type.

Another aspect of the present invention includes a method for manufacturing a semiconductor device having alternating first type and second type semiconductor conductive regions, which comprises the following steps:

step 1: form a first type epitaxial layer on a first type substrate; deposit a dielectric layer on the first type epitaxial layer; form a trench in the first type epitaxial layer by lithography and etch; wherein, the first type substrate has a high impurity concentration;

step 2: form a carbon film on sidewalls of the trench by carbon diffusion process;

step 3: till the trench by depositing a second type semiconductor layer, wherein the second type semiconductor layer is a single layer of second type silicon, or a combination of a second type silicon layer and a dielectric film, or a combination of a second type silicon layer and a non-doped silicon layer;

The second type semiconductor layer can be made of monocrystal silicon, polycrystal silicon or amorphous silicon; the growth temperature of monocrystal silicon can be in a range of 650-1200; the growth temperature of polycrystal silicon can be in a range of 580-650; the growth temperature of amorphous silicon can be in a range of 510-579.

step 4: remove a part of the second type semiconductor layer, the carbon film and the dielectric layer above the first type epitaxial layer by CMP or etch-back process;

In the above-mentioned method, the first type is N type when the second type is P type; the first type is P type when the second type is N type.

Another aspect of the present invention includes a semiconductor device having alternating N type and P type semiconductor layers, wherein a carbon-contained silicon layer or a carbon film is formed between an N type semiconductor layer and a P type semiconductor layer.

The present invention can effectively inhibit the diffusion of P type impurities into N type semiconductor layers or N type impurities into P type semiconductor layers during high temperature processes by forming a carbon-contained silicon layer or a carbon, film between the N type and P type semiconductor layers. Therefore, the neutralization of N type carriers in N type semiconductor layers or P type carriers in P type semiconductor layers is mitigated, thus achieving a low Rsp (specific on resistance) of the device.

### BRIEF DESCRIPTION OF THE DRAWINGS

FIGS. 1A˜1D are sectional views of the method for manufacturing semiconductor device according to a first embodiment of the present invention.

FIG. 2 is a schematic view showing a superjunction NMOSFET according to the first embodiment of the present invention.

FIGS. 3A˜D are sectional views of the method for manufacturing semiconductor device according to a second embodiment of the present invention.

### DETAILED DESCRIPTION OF THE INVENTION

In the following embodiments of the present invention, a 600V superjunction NMOSFET will be taken as an example to give some detailed explanations. Those skilled in the art shall understand that the same structure and manufacturing method can also be applied to a PMOSFET by changing all the N-types to P-types and P-types to N-types.

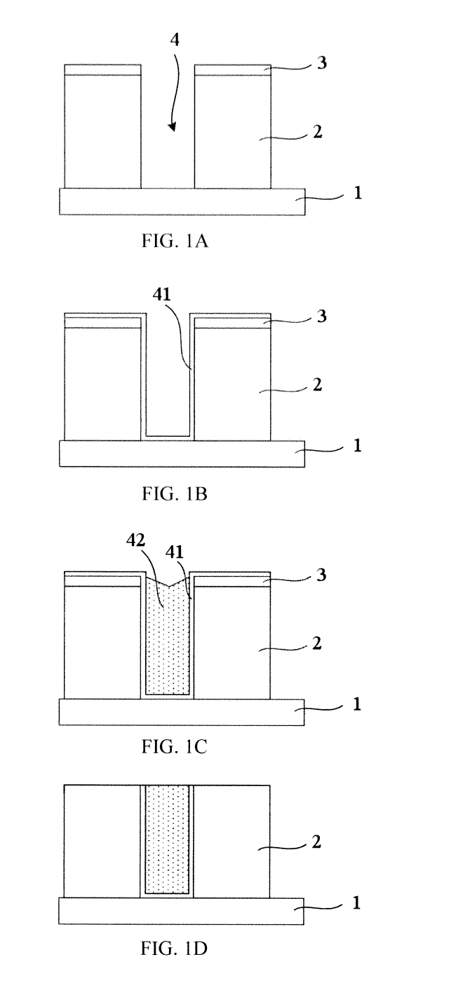

FIGS. 1A˜1D are sectional views of the manufacturing method of semiconductor device according to a first embodiment of the present invention. The method is used to form alternating P type and N type semiconductor conductive regions for a superjunction semiconductor device. The method comprises the following steps:

Step 1: as shown in FIG. 1A, form an N type epitaxial layer 2 on top of an N+ substrate 1; deposit a dielectric layer 3 on top of the N type epitaxial layer 2; and form a trench 4 in the N type epitaxial layer 2 by lithography and etch.

The N+ substrate 1 has a resistivity of 0.001˜0.003 ohm·cm. The resistivity and thickness of the N type epitaxial layer 2 are determined according to the design requirement of the device. For a superjunction NMOSFET having a 600V breakdown voltage at drain/source (BVDS), the resistivity and thickness of the N type epitaxial layer 2 are designed to be 2˜10 ohm·cm and 40˜55 μm, respectively.

The dielectric layer 3 can be made of an oxide layer, the thickness of which is about 10000˜20000 angstrom. In this embodiment, the oxide layer can be formed by thermal oxidation or by CVD (chemical vapor deposition) process. The dielectric layer 3 can be used as a hard mask during the step of trench etching and can also be used as a stop layer in a subsequent process of CMP.

The trench 4 may be etched by using the dielectric layer (oxide layer) 3 as hard mask, or by using a layer of photo resist as mask. In both ways, the remaining oxide layer after trench etching is suggested to be more than 1000 angstrom. The trench 4 may pass through the N type epitaxial layer 2 and connect with the N+ substrate 1 or may stop in the N type epitaxial layer 2. Although only one trench is shown in FIG. 1A, those skilled in the art shall understand that the number of trenches is not limited to one. Two or more trenches may be simultaneously formed in the N type epitaxial layer.

Step 2: as shown in FIG. 1B, form a carbon-contained silicon layer 41 on side walls (including side surfaces and a bottom surface) of the trench 4.

The carbon-contained silicon layer 41 can be N-typed, P-typed or intrinsic. The thickness of the carbon-contained silicon layer 41 is less than 3000 angstrom. The impurity concentration of carbon in the carbon-contained silicon layer 41 is higher than the impurity concentration of P type carrier in the P type semiconductor layer 42 to be filled in the trench in subsequent process, and preferably, the concentration of carbon is at least one order of magnitude higher. If the carbon-contained silicon layer 41 is P-typed, the P type impurity concentration of the layer 41 should be of the same order of magnitude as the P type impurity concentration of the P type semiconductor layer 42 to be formed; if the carbon-contained silicon layer 41 is N-typed, the N type impurity concentration of the layer 41 should be of the same order of magnitude as the N type impurity concentration of the N type epitaxial layer 2.

Step 3: as shown in FIG. 1C, fill the trench with a P type semiconductor layer 42, wherein the P type semiconductor layer 42 can be a single layer of P type silicon, or a combination of a P type silicon layer and a dielectric film, or a combination of a P type silicon layer and a non-doped silicon layer.

The impurities in the P type semiconductor layer 42 are used to compensate the N type impurities in the neighboring N type regions. In order to get an ideal breakdown voltage performance, the total amount of P type impurities in P type regions should be equal to the total amount of N type impurities in N type regions. Take one trench 4 with a carbon-contained silicon layer 41 and a P type semiconductor layer 42 formed therein for example, there are N type epitaxial layers 2 at both sides of the trench 4. When the carbon-contained silicon layer 41 is P-typed, the total amount of P type impurities in the P type layers 41 and 42 should be equal to the amount of N type impurities in the neighboring N type epitaxial layers 2 at both sides of the trench 4; when the carbon-contained silicon layer 41 is N-typed, the amount of P type impurities in the P type semiconductor layer 42 should be equal to the total amount of N type impurities in the N type carbon-contained silicon layer 41 and the neighboring N type epitaxial layers 2 at both sides.

To achieve a completely filled trench without void, a relatively simple way is to form the P type semiconductor layer 42 by a combination of a P type silicon layer and a dielectric film such as BPSG. The P type silicon layer can be deposited first, and followed by the BPSG dielectric film. The trench can be easily filled by taking advantage of the reflow property of the BPSG film.

Another way is to form the P type semiconductor layer 42 by a combination of a P type silicon layer and a non-doped silicon layer. The P type silicon layer can be deposited first, and followed by the non-doped silicon layer. Since there will be no large leakage current in the non-doped silicon layer even if small voids exist, a reasonably good electrical performance of the device can be achieved by adopting this process.

The above mentioned P type silicon layer can be made of monocrystal silicon, polycrystal silicon or amorphous silicon, wherein the growth temperature of P type monocrystal silicon may be in a range of 650˜1200; the growth temperature of P type polycrystal silicon may be in a range of 580˜650; the growth temperature of P type amorphous silicon may be in a range of 510˜579.

Step 4: as shown in FIG. 1D, remove a part of the P type semiconductor layer 42 and the carbon-contained silicon layer 41 above the N type epitaxial layer 2 by CMP or etch-back, and then remove the dielectric layer 3. To ensure that the silicon surface under the dielectric layer 3 is not to be damaged during the CMP process, it is suggested that a thickness of more than 500 angstrom of the dielectric layer 3 be remained after CMP.

By using the aforementioned steps 1˜4, a semiconductor device having alternating N type and P type semiconductor conductive regions is formed, wherein a layer of carbon-contained silicon layer exists between the N type and P type conductive regions.

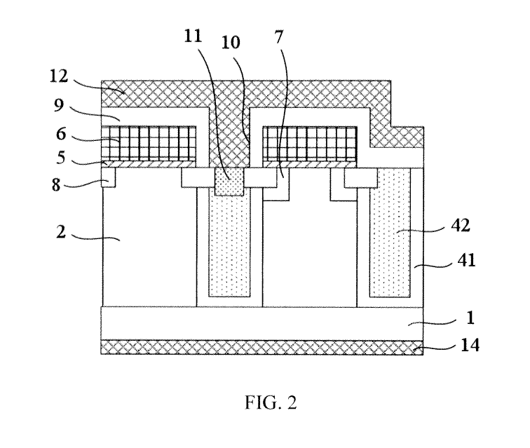

Afterwards, as shown in FIG. 2, by using conventional vertical MOSFET processes, further steps are taken to produce a corresponding superjunction NMOS device as follows:

Step 5: form polysilicon gates 6 by processes of gate oxidation, polysilicon deposition and polysilicon patterning. Normally, the gate oxide layer 5 formed by gate oxidation has a thickness of 800˜1000 angstrom, and the polysilicon layer formed by polysilicon deposition has a thickness of 2000˜4000 angstrom.

Step 6: form P wells 7 by P type implantation and drive-in process.

Step 7: N+ layers 8 are formed by N+ lithography and N+ implantation.

Step 8: form an inter layer dielectric film 9 on the polysilicon gates 6 to isolate polysilicon from metal. Then, form contact holes 10 by contact lithography and etch. Afterwards, form a P+ ohmic contact region 11 for P well by P+ lithography and implantation. Normally, the thickness of the inter layer dielectric film 9 is 8000˜10000 angstrom.

Step 9: deposit a metal layer and pattern the metal layer to form source electrodes 12 and gate electrodes (connecting to gates 6) by metal lithography and etch. The thickness of the metal layer is 20000˜40000 angstrom, normally.

Step 10: form drain electrode 14 at the backside of the N+ substrate 1 by backside grinding and backside metallization.

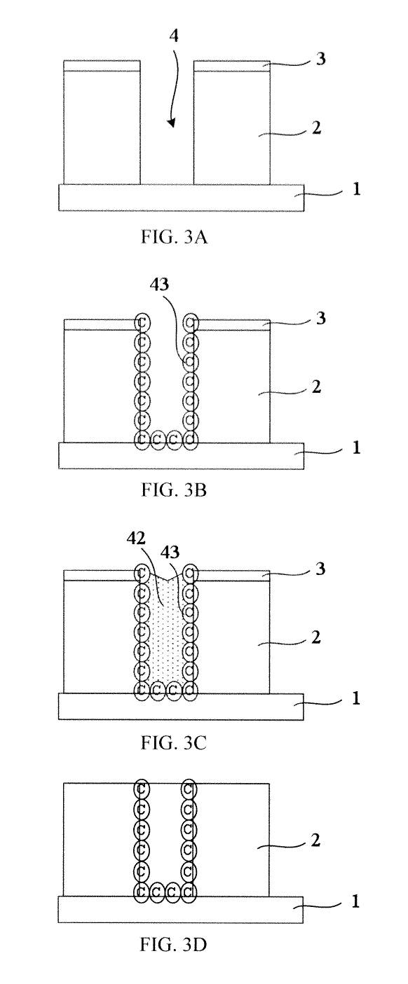

FIG. 3A˜FIG. 3D are sectional views of the method for manufacturing semiconductor device according to a second embodiment of the present invention. In the second embodiment, the manufacturing method also comprises four steps, wherein steps 1 and 3 are the same as the corresponding steps in the first embodiment, while step 2 is different in that no carbon-contained silicon layer 41 is deposited; instead, a carbon film 43 is formed on sidewalls (including side surfaces and a bottom surface) of the trench by carbon diffusion process. The diffusion process enables the adsorption of the carbon film 43 on the trench surface. It is suggested that the concentration of carbon in the carbon film 43 after subsequent high temperature processes be higher than the P type impurity concentration in the P type semiconductor layer 42 formed in step 3, preferably at least one order of magnitude higher. In step 4, a part of the P type semiconductor layer 42, the carbon film 43 and the dielectric layer 3 above the N type epitaxial layer 2 is removed by CMP or etch-back process. It is also suggested that a thickness of more than 500 angstrom of the dielectric layer 3 be remained after CMP.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A method for manufacturing a semiconductor device having alternating first type and second type semiconductor layers, comprising the following steps:
step 1: forming a first type epitaxial layer on a first type substrate; depositing a dielectric layer on the first type epitaxial layer; forming a trench in the first type epitaxial layer by lithography and etch;
step 2: depositing a carbon-contained silicon layer on sidewalls of the trench;
step 3: filling the trench by depositing a second type semiconductor layer, wherein the second type semiconductor layer is a single layer of second type silicon, or a combination of a second type silicon layer and a dielectric film, or a combination of a second type silicon layer and a non-doped silicon layer;
step 4: removing a part of the second type semiconductor layer, the carbon-contained silicon layer and the dielectric layer above the first type epitaxial layer by CMP or etch-back process;
wherein, the first type is N type when the second type is P type; the first type is P type when the second type is N type.

2. The method according to claim 1, wherein, the carbon-contained silicon layer is P-typed, N-typed or intrinsic.

3. The method according to claim 1, wherein, the second type silicon layer is made of monocrystal silicon, polycrystal silicon or amorphous silicon.

4. The method according to claim 3, wherein, a growth temperature of the monocrystal silicon is in a range of 650˜1200.

5. The method according to claim 3, wherein, a growth temperature of the polycrystal silicon is in a range of 580˜650.

6. The method according to claim 3, wherein, a growth temperature of the amorphous silicon is in a range of 510˜579.

7. The method according to claim 1, wherein, the first type substrate has a high impurity concentration.

8. The method according to claim 1, wherein, the dielectric layer deposited on the first type epitaxial layer is an oxide layer.

9. The method according to claim 1, wherein, the dielectric film in step 3 is made of BPSG.

10. A method for manufacturing a semiconductor device having alternating first type and second type semiconductor layers, comprising the following steps:
step 1: forming a first type epitaxial layer on a first type substrate; depositing a dielectric layer on the first type epitaxial layer; forming a trench in the first type epitaxial layer by lithography and etch;
step 2: forming a carbon film on sidewalls of the trench by carbon diffusion process;
step 3: tilling the trench by depositing a second type semiconductor layer, wherein the second type semiconductor layer is a single layer of second type silicon, or a combination of a second type silicon layer and a dielectric film, or a combination of a second type silicon layer and a non-doped silicon layer;
step 4: removing a part of the second type semiconductor layer, the carbon film and the dielectric layer above the first type epitaxial layer by CMP or etch-back process;
wherein, the first type is N type when the second type is P type; the first type is P type when the second type is N type.

11. The method according to claim 10, wherein, the second type silicon layer is made of monocrystal silicon, polycrystal silicon or amorphous silicon.

12. The method according to claim 11, wherein, a growth temperature of the monocrystal silicon is in a range of 650˜1200.

13. The method according to claim 11, wherein, a growth temperature of he polycrystal silicon is in a range of 580˜650.

14. The method according to claim 11, wherein, a growth temperature of the amorphous silicon is in a range of 510˜579.

15. The method according to claim 10, wherein, the first type substrate has a high impurity concentration.

16. The method according to claim 10, wherein, the dielectric layer deposited on the first type epitaxial layer is an oxide layer.

17. The method according to claim 10, wherein, the dielectric film in step 3 is made of BPSG.

18. A semiconductor device having alternating N type and P type semiconductor layers, wherein a carbon-contained silicon layer or a carbon film is formed between an N type semiconductor layer and a P type semiconductor layer.
